(19) United States
(12) Patent Application Publication
(10) Pub. No.: US 2020/0266301 A1
(43) Pub. Date: Aug. 20, 2020

(54) ARRAY SUBSTRATE AND DISPLAY PANEL

(71) Applicant: WUHAN CHINA STAR OPTOELECTRONICS TECHNOLOGY CO., LTD., Wuhan (CN)

(72) Inventor: Guangyu CAI, Wuhan (CN)

(73) Assignee: WUHAN CHINA STAR OPTOELECTRONICS TECHNOLOGY CO., LTD., Wuhan (CN)

(21) Appl. No.: 16/466,657

(22) PCT Filed: Feb. 20, 2019
(86) PCT No.: PCT/CN2019/075611

§ 371 Date: Jun. 5, 2019

(51) Int. Cl. H01L 29/786; H01L 27/12

(52) U.S. Cl. CPC H01L 29/78621; H01L 29/78633; H01L 27/124

(57) ABSTRACT

The present invention provides an array substrate and a display panel. The array substrate includes a first metal layer and an active layer. The first metal layer includes a first metal unit at the middle and a second metal unit and a third metal unit at two sides of the first metal unit. The active layer includes a channel region at the middle and a doped source region and a doped drain region at two sides of the channel region. The first metal unit is arranged corresponding to the channel region. The second metal unit and the third metal unit are connected to the doped source region and the doped drain region, respectively.

### 1. FIELD OF DISCLOSURE

The present invention relates to a field of display devices and in particular, to an array substrate and a display panel.

### 2. DESCRIPTION OF RELATED ART

It is known that liquid crystal displays include a display panel and a backlight module. The display panel is constituted by a color filter substrate, an array substrate, and a liquid crystal layer disposed between the color filter substrate and the array substrate. A working principle of the display panel is to control rotation of liquid crystal molecules of the liquid crystal layer by applying a driving voltage, and refract light from the backlight module to form an image.

The array substrate usually uses a semiconductor device such as a thin film transistor (TFT) as a switching element to control a pixel unit to receive image data or not. It is well known that TFTs need a semiconductor material to constitute a conductive channel, and light is transmitted in the display panel. However, when the semiconductor material receives light, it easily causes a photoelectric effect. Switching functions of the TFTs are affected when the semiconductor material in the conductive channel produces a photoelectric effect. Therefore, the display panel is provided with a light-shielding layer at a position corresponding to the conductive channel of the TFT. However, the light-shielding layer needs to be developed by a separate process, thus increasing production costs of the array substrate.

### SUMMARY

The present invention provides a display panel and a manufacturing method thereof to solve a problem of high production costs of conventional array substrates.

In order to solve the above-mentioned problem, the present invention provides a solution as follows.

According to one aspect of the present invention, an array substrate is provided, comprising:

a base substrate;

a first metal layer disposed on the base substrate, the first metal layer comprising a first metal unit at the middle and a second metal unit and a third metal unit at two sides of the first metal unit;

a first insulating layer disposed on the first metal layer;

an active layer disposed on the first insulating layer, the active layer comprising a channel region at the middle and a doped source region and a doped drain region at two sides of the channel region;

a second insulating layer disposed on the active layer; and

a second metal layer disposed on the second insulating layer;

wherein the first metal unit is connected to at most one of the second metal unit and the third metal unit, the first metal unit is disposed corresponding to the channel region for shielding light from reaching the channel region, and the second metal unit and the third metal unit are connected to the doped source region and the doped drain region, respectively.

According to one embodiment of the preset invention, the first metal unit is a light-shielding metal, the second metal unit is a source electrode metal, and the third metal unit is a drain electrode metal.

According to one embodiment of the present invention, a first through hole and a second through hole are defined in the first insulating layer, the doped source region is connected to the second metal unit through the first through hole, and the doped drain region is connected to the third metal unit through the second through hole.

According to one embodiment of the present invention, the second metal layer consists of a gate electrode metal, and the gate electrode metal is located corresponding to the channel region.

According to one embodiment of the present invention, the active layer further comprises a first lightly doped region and a second lightly doped region, the first lightly doped region is disposed between the doped source region and the channel region, and the second lightly doped region is disposed between the doped drain region and the channel region.

According to one embodiment of the present invention, the array substrate further comprises:

a planarization layer disposed on the second metal layer;

a first transparent electrode layer disposed on the planarization layer;

a passivation layer disposed on the first transparent electrode layer; and

a second transparent electrode layer disposed on the passivation layer.

According to one embodiment of the present invention, a third through hole is defined in the array substrate, and the third through hole penetrates through the passivation layer, the planarization layer, the second insulating layer, and the first insulating layer, wherein the second transparent electrode layer is connected to the third metal unit through the third through hole.

According to one embodiment of the present invention, the first transparent electrode layer and the second transparent electrode layer are electrically insulated from each other.

According to one embodiment of the present invention, the first metal unit, the second metal unit, and the third metal unit are made in a same photomask process.

According to one embodiment of the present invention, the first metal unit, the second metal unit, and the third metal unit are made of a same material.

According another aspect of the present invention, a display panel is provided, the display panel comprising a backlight module and an array substrate, the array substrate comprising:

a base substrate;

a first metal layer disposed on the base substrate, the first metal layer comprising a first metal unit at the middle and a second metal unit and a third metal unit at two sides of the first metal unit;

a first insulating layer disposed on the first metal layer;

an active layer disposed on the first insulating layer, the active layer comprising a channel region at the middle and a doped source region and a doped drain region at two sides of the channel region;

a second insulating layer disposed on the active layer; and

a second metal layer disposed on the second insulating layer;

wherein the first metal unit is connected to at most one of the second metal unit and the third metal unit, the first metal unit is disposed corresponding to the channel region for shielding light from reaching the channel region, and the second metal unit and the third metal unit are connected to the doped source region and the doped drain region, respectively.

According to one embodiment of the present invention, the first metal unit is a light-shielding metal, the second metal unit is a source electrode metal, and the third metal unit is a drain electrode metal.

According to one embodiment of the present invention, a first through hole and a second through hole are defined in the first insulating layer, the doped source region is connected to the second metal unit through the first through hole, and the doped drain region is connected to the third metal unit through the second through hole.

According to one embodiment of the present invention, the second metal layer consists of a gate electrode metal, and the gate electrode metal is disposed corresponding to the channel region.

According to one embodiment of the present invention, the active layer further comprises a first lightly doped region and a second lightly doped region, the first lightly doped region is disposed between the doped source region and the channel region, and the second lightly doped region is disposed between the doped drain region and the channel region.

According to one embodiment of the present invention, the display panel further comprising:

a planarization layer disposed on the second metal layer;

a first transparent electrode layer disposed on the planarization layer;

a passivation layer disposed on the first transparent electrode layer; and

a second transparent electrode layer disposed on the passivation layer.

According to one embodiment of the present invention, a third through hole is defined in the array substrate, the third through hole penetrates through the passivation layer, the planarization layer, the second insulating layer, and the first insulating layer; wherein the second transparent electrode layer is connected to the third metal unit through the third through hole.

According to one embodiment of the present invention, the first transparent electrode layer and the second transparent electrode layer are electrically insulated from each other.

According to one embodiment of the present invention, the first metal unit, the second metal unit, and the third metal unit are made in a same photomask process.

According to one embodiment of the present invention, the first metal unit, the second metal unit, and the third metal unit are made of a same material.

Advantageous effects: In the present invention, the light-shielding metal, the source metal, and the drain metal are in the same layer, thereby not only saving one insulating layer, but also reducing one photomask process, which leads to reduction of production costs.

### BRIEF DESCRIPTION OF DRAWINGS

In order to more clearly illustrate the embodiments of the present disclosure or related art, figures which will be described in the embodiments are briefly introduced hereinafter. It is obvious that the drawings are merely for the purposes of illustrating some embodiments of the present disclosure, and a person having ordinary skill in this field can obtain other figures according to these figures without an inventive work or paying the premise.

FIG. 1 is a schematic structural view illustrating an array substrate according to a first embodiment of the present invention;

FIG. 2 is a schematic structural view illustrating the array substrate according to a second embodiment of the present invention; and

FIG. 3 is a top view illustrating the array substrate according to a third embodiment of the present invention.

### DETAILED DESCRIPTION OF EMBODIMENTS

Embodiments of the present disclosure are described in detail with reference to the accompanying drawings as follows. Directional terms such as up/down, right/left, inner/outer, and the like may be used for the purpose of enhancing a reader's understanding about the accompanying drawings, but are not intended to be limiting. Specifically, the terminologies in the embodiments of the present disclosure are merely for the purpose of describing certain embodiments, but not intended to limit the scope of the invention. The same reference numbers are used throughout the drawings to refer to the same or similar parts.

The present application provides a display panel and a manufacturing method thereof to solve a problem of high production costs of conventional array substrates.

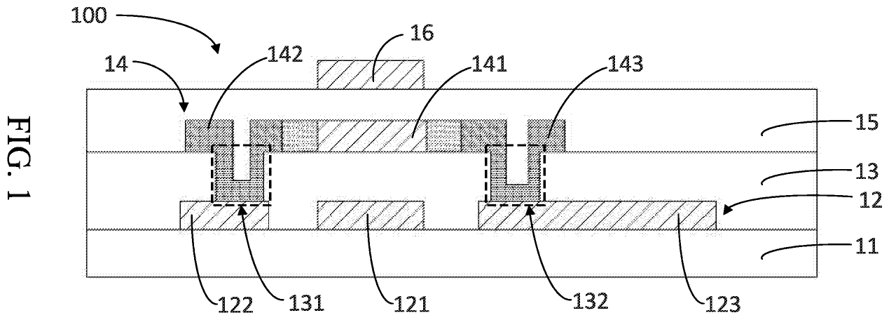

Please refer to FIG. 1, which is a schematic structural view illustrating an array substrate 100 according to a first embodiment of the present invention.

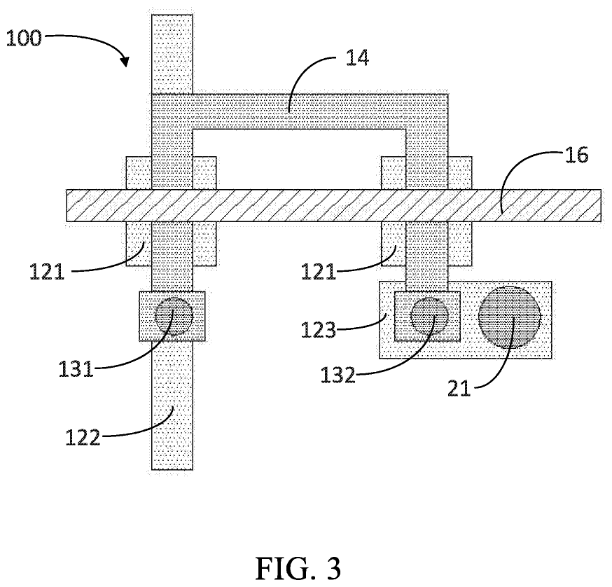

Please refer to FIG. 3 which is a top structural view illustrating an array substrate 100 according to a third embodiment of the present invention.

According to one aspect of the present invention, the array substrate 100 is provided. The array substrate 100 comprises a base substrate 11, a first metal layer 12, a first insulating layer 13, an active layer 14, a second insulating layer 15, and a second metal layer 16.

According to one embodiment of the present invention, the base substrate 11 is one of a flexible substrate and a rigid substrate.

The first metal layer 12 is disposed on the base substrate 11. The first metal layer 12 comprises a first metal unit 121 at the middle and a second metal unit 122 and a third metal unit 123 at two sides of the first metal unit 121.

According to one embodiment of the present invention, the first metal unit 121 is a light-shielding metal for shielding light from reaching a channel region 141 of the active layer 14, the second metal unit 122 is a source electrode metal, and the third metal unit 123 is a drain electrode metal.

According to one embodiment of the present invention, the first metal layer 12 is made of molybdenum.

According to one embodiment of the present invention, the first metal unit 121, the second metal unit 122, and the third metal unit 123 are made of a same material.

According to one embodiment of the present invention, the first metal unit 121, the second metal unit 122, and the third metal unit 123 are made in a same photomask process, thereby reducing one photomask process.

According to one embodiment of the present invention, the first metal unit 121 is connected to at most one of the second metal unit 122 and the third metal unit 123, so that the second metal unit 122 and the third metal unit 123 are prevented from being connected to each other to cause a short circuit.

According to one embodiment of the present invention, the first metal unit 121, the second metal unit 122, and the third metal unit 123 are electrically insulated from each other.

According to one embodiment of the present invention, the first metal unit 121 is connected to the second metal unit 122 and electrically insulated from the third metal unit 123.

According to one embodiment of the present invention, the first metal unit 121 is connected to the third metal unit 123 and electrically insulated from the second metal unit 122.

The first insulating layer 13 is disposed on the first metal layer 12.

According to one embodiment of the present invention, the first insulating layer 13 is made of at least one of silicon nitride and silicon oxide.

According to one embodiment of the present invention, the first insulating layer 13 comprises a silicon oxide layer and a silicon nitride layer.

The active layer 14 is disposed on the first insulating layer 13, the active layer 14 comprises a channel region 141 at the middle and a doped source region 142 and a doped drain region 143 at two sides of the channel region 141.

According to one embodiment of the present invention, the channel region 141 is disposed corresponding to the first metal unit 121.

According to one embodiment of the present invention, the active layer 14 further comprises a first lightly doped region 144 and a second lightly doped region 145, the first lightly doped region 144 is disposed between the doped source region 142 and the channel region 141, and the second lightly doped region 145 is disposed between the doped drain region 143 and the channel region 141. The presence of the first lightly doped region 144 and the second lightly doped region 145 can enhance electrical properties of a thin film transistor.

According to one embodiment of the present invention, the second insulating layer 15 is disposed on the active layer 14.

According to one embodiment of the present invention, material of the second insulating layer 15 comprises silicon nitride.

According to one embodiment of the present invention, the second metal layer 16 is disposed on the second insulating layer 15.

According to one embodiment of the present invention, the second metal layer 16 consists of a gate electrode metal.

The first metal unit 121 is disposed corresponding to the channel region 141 for shielding light from reaching the channel region 141, and the second metal unit 122 and the third metal unit 123 are connected to the doped source region 142 and the doped drain region 143, respectively.

In the present application, the source electrode metal and the drain electrode metal are disposed under the active layer 14. The light-shielding metal, the source electrode metal, and the drain electrode metal in the array substrate 100 are disposed in the same layer. A polysilicon layer is connected to the source electrode metal and the drain electrode metal through a hole defined in the first insulating layer 13, so that one insulating layer can be omitted to save one photomask process.

According to one embodiment of the present invention, a first through hole 131 and a second through hole 132 are defined in the first insulating layer 13, the doped source region 142 is connected to the second metal unit 122 through the first through hole 131, and the doped drain region 143 is connected to the third metal unit 123 through the second through hole 132.

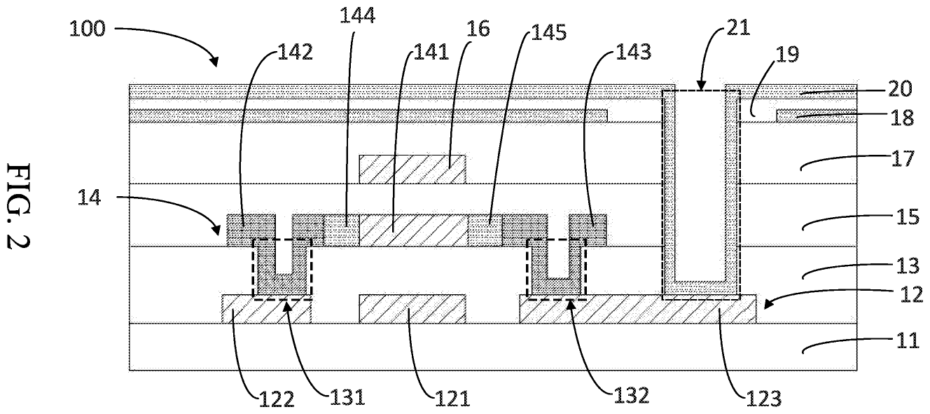

Please refer to FIG. 2, which is a schematic structural view illustrating the array substrate 100 according to a second embodiment of the present invention.

According to one embodiment of the present invention, the array substrate 100 comprises a planarization layer 17 disposed on the second metal layer 16, a first transparent electrode layer 18, a passivation layer 19, and a second transparent electrode layer 20.

According to one embodiment of the present invention, a third through hole 21 is defined in the array substrate 100, and the third through hole 21 penetrates through the passivation layer 19, the planarization layer 17, the second insulating layer 15, and the first insulating layer 13; and wherein the second transparent electrode layer 20 is connected to the third metal unit 123 through the third through hole 21.

According to one embodiment of the present invention, the first transparent electrode layer 18 and the second transparent electrode layer 20 are electrically insulated from each other.

According to another aspect of the present invention, a display panel is provided, the display panel comprising a backlight module and an array substrate 100, the array substrate 100 comprising:

a base substrate 11;

a first metal layer 12 disposed on the base substrate 11, the first metal layer 12 comprising a first metal unit 121 at the middle and a second metal unit 122 and a third metal unit 123 at two sides of the first metal unit 121;

a first insulating layer 13 disposed on the first metal layer 12;

an active layer 14 disposed on the first insulating layer 13, the active layer 14 comprising a channel region 141 at the middle and a doped source region 142 and a doped drain region 143 at two sides of the channel region 141;

a second insulating layer 15 disposed on the active layer 14; and

a second metal layer 16 disposed on the second insulating layer 15;

wherein the first metal unit 121 is connected to at most one of the second metal unit 122 and the third metal unit 123, the first metal unit 121 is disposed corresponding to the channel region 141 for shielding light from reaching the channel region 141, and the second metal unit 122 and the third metal unit 123 are connected to the doped source region 142 and the doped drain region 143, respectively.

According to one embodiment of the present invention, the first metal unit 121 is a light-shielding metal, the second metal unit 122 is a source electrode metal, and the third metal unit 123 is a drain electrode metal.

According to one embodiment of the present invention, a first through hole 131 and a second through hole 132 are defined in the first insulating layer 13, the doped source region 142 is connected to the second metal unit 122 through the first through hole 131, and the doped drain region 143 is connected to the third metal unit 123 through the second through hole 132.

According to one embodiment of the present invention, the second metal layer 16 consists of a gate electrode metal, and the gate electrode metal is disposed corresponding to the channel region 141.

According to one embodiment of the present invention, the active layer 14 further comprises a first lightly doped region 144 and a second lightly doped region 145, the first lightly doped region 144 is disposed between the doped source region 142 and the channel region 141, and the second lightly doped region 145 is disposed between the doped drain region 143 and the channel region 141.

According to one embodiment of the present invention, the array substrate 100 further comprises;

a planarization layer 17 disposed on the second metal layer 16;

a first transparent electrode layer 18 disposed on the planarization layer 17;

a passivation layer 19 disposed on the first transparent electrode layer 18; and

a second transparent electrode layer 20 disposed on the passivation layer 19.

According to one embodiment of the present invention, a third through hole 21 is defined in the array substrate 100, the third through hole 21 penetrates through the passivation layer 19, the planarization layer 17, the second insulating layer 15, and the first insulating layer 13; wherein the second transparent electrode layer 20 is connected to the third metal unit 123 through the third through hole 21.

According to one embodiment of the present invention, the first transparent electrode layer 18 and the second transparent electrode layer 20 are electrically insulated from each other.

According to one embodiment of the present invention, the first metal unit 121, the second metal unit 122, and the third metal unit 123 are made in a same photomask process.

Advantageous effects: In the present invention, the light-shielding metal, the source metal, and the drain metal are in the same layer, thereby not only saving one insulating layer, but also reducing one photomask process, which leads to reduction of production costs.

It is to be understood that the above descriptions are merely the preferable embodiments of the present invention and are not intended to limit the scope of the present invention. Equivalent changes and modifications made in the spirit of the present invention are regarded as falling within the scope of the present invention.

What is claimed is:

1. An array substrate, comprising:
a base substrate;
a first metal layer disposed on the base substrate, the first metal layer comprising a first metal unit at the middle and a second metal unit and a third metal unit at two sides of the first metal unit;
a first insulating layer disposed on the first metal layer;
an active layer disposed on the first insulating layer, the active layer comprising a channel region at the middle and a doped source region and a doped drain region at two sides of the channel region;
a second insulating layer disposed on the active layer; and
a second metal layer disposed on the second insulating layer;
wherein the first metal unit is connected to at most one of the second metal unit and the third metal unit, the first metal unit is disposed corresponding to the channel region for shielding light from reaching the channel region, and the second metal unit and the third metal unit are connected to the doped source region and the doped drain region, respectively.

2. The array substrate according to claim 1, wherein the first metal unit is a light-shielding metal, the second metal unit is a source electrode metal, and the third metal unit is a drain electrode metal.

3. The array substrate according to claim 1, wherein a first through hole and a second through hole are defined in the first insulating layer, the doped source region is connected to the second metal unit through the first through hole, and the doped drain region is connected to the third metal unit through the second through hole.

4. The array substrate according to claim 1, wherein the second metal layer consists of a gate electrode metal, and the gate electrode metal is located corresponding to the channel region.

5. The array substrate according to claim 1, wherein the active layer further comprises a first lightly doped region and a second lightly doped region, the first lightly doped region is disposed between the doped source region and the channel region, and the second lightly doped region is disposed between the doped drain region and the channel region.

6. The array substrate according to claim 1, further comprising:
a planarization layer disposed on the second metal layer;
a first transparent electrode layer disposed on the planarization layer;
a passivation layer disposed on the first transparent electrode layer; and
a second transparent electrode layer disposed on the passivation layer.

7. The array substrate according to claim 6, wherein a third through hole is defined in the array substrate, and the third through hole penetrates through the passivation layer, the planarization layer, the second insulating layer, and the first insulating layer; and
wherein the second transparent electrode layer is connected to the third metal unit through the third through hole.

8. The array substrate according to claim 7, wherein the first transparent electrode layer and the second transparent electrode layer are electrically insulated from each other.

9. The array substrate according to claim 1, wherein the first metal unit, the second metal unit, and the third metal unit are made in a same photomask process.

10. The array substrate according to claim 9, wherein the first metal unit, the second metal unit, and the third metal unit are made of a same material.

11. A display panel, the display panel comprising a backlight module and an array substrate, the array substrate comprising:
a base substrate;
a first metal layer disposed on the base substrate, the first metal layer comprising a first metal unit at the middle and a second metal unit and a third metal unit at two sides of the first metal unit;
a first insulating layer disposed on the first metal layer;
an active layer disposed on the first insulating layer, the active layer comprising a channel region at the middle and a doped source region and a doped drain region at two sides of the channel region;
a second insulating layer disposed on the active layer; and
a second metal layer disposed on the second insulating layer;
wherein the first metal unit is connected to at most one of the second metal unit and the third metal unit, the first metal unit is disposed corresponding to the channel region for shielding light from reaching the channel region, and the second metal unit and the third metal unit are connected to the doped source region and the doped drain region, respectively.

12. The display panel according to claim 11, wherein the first metal unit is a light-shielding metal, the second metal unit is a source electrode metal, and the third metal unit is a drain electrode metal.

13. The display panel according to claim 11, wherein a first through hole and a second through hole are defined in the first insulating layer, the doped source region is connected to the second metal unit through the first through hole, and the doped drain region is connected to the third metal unit through the second through hole.

14. The display panel according to claim 11, wherein the second metal layer consists of a gate electrode metal, and the gate electrode metal is disposed corresponding to the channel region.

15. The display panel according to claim 11, wherein the active layer further comprises a first lightly doped region and a second lightly doped region, the first lightly doped region is disposed between the doped source region and the channel region, and the second lightly doped region is disposed between the doped drain region and the channel region.

16. The display panel according to claim 11, further comprising:
a planarization layer disposed on the second metal layer;
a first transparent electrode layer disposed on the planarization layer;
a passivation layer disposed on the first transparent electrode layer; and
a second transparent electrode layer disposed on the passivation layer.

17. The display panel according to claim 16, wherein a third through hole is defined in the array substrate, the third through hole penetrates through the passivation layer, the planarization layer, the second insulating layer, and the first insulating layer;
wherein the second transparent electrode layer is connected to the third metal unit through the third through hole.

18. The display panel according to claim 17, wherein the first transparent electrode layer and the second transparent electrode layer are electrically insulated from each other.

19. The display panel according to claim 11, wherein the first metal unit, the second metal unit, and the third metal unit are made in a same photomask process.

20. The display panel according to claim 19, wherein the first metal unit, the second metal unit, and the third metal unit are made of a same material.
